(19) United States
(12) Patent Application Publication
(10) Pub. No.: US 2024/0395747 A1
(43) Pub. Date: Nov. 28, 2024

(54) SEMICONDUCTOR PACKAGE AND METHOD OF INSPECTING THE SEMICONDUCTOR PACKAGE

(71) Applicant: Samsung Electronics Co., Ltd., Suwon-si (KR)

(72) Inventors: Jaekul Lee, Suwon-si (KR); Hyungsun Jang, Suwon-si (KR); Sanguk Han, Suwon-si (KR); Taehun Kim, Suwon-si (KR)

(21) Appl. No.: 18/638,757

(22) Filed: Apr. 18, 2024

(30) Foreign Application Priority Data
May 24, 2023 (KR) 10-2023-0066692

(51) Int. Cl. H01L 23/00

(52) U.S. Cl. CPC H01L 24/05; H01L 24/13; H01L 24/20; H01L 24/73; H01L 2224/05548; H01L 2224/05611; H01L 2224/05624; H01L 2224/05639; H01L 2224/05644; H01L 2224/05647; H01L 2224/05655; H01L 2224/05666; H01L 2224/05671; H01L 2224/0568; H01L 2224/05684; H01L 2224/13006; H01L 2224/211; H01L 2224/73101; H01L 2924/3511

(57) ABSTRACT

A semiconductor package may include a semiconductor chip having a first surface and a second surface opposite to the first surface and having a plurality of circuit patterns provided in the second surface, a redistribution wiring layer on the second surface of the semiconductor chip and having a plurality of redistribution wirings and a plurality of bonding pads, the redistribution wirings being electrically connected to the circuit patterns, the bonding pads electrically connected to the redistribution wirings and exposed from a lower surface, a plurality of conductive bumps on the plurality of bonding pads, respectively, and a plurality of spacers on the lower surface of the redistribution wiring layer and configured to align the plurality of conductive bumps through respective through holes of a test socket and to space the redistribution wiring layer from the test socket.

### CROSS-REFERENCE TO RELATED APPLICATION(S)

This application claims priority under 35 U.S.C. § 119 to Korean Patent Application No. 10-2023-0066692, filed on May 24, 2023 in the Korean Intellectual Property Office (KIPO), the disclosure of which is herein incorporated by reference in its entirety.

### BACKGROUND

Example embodiments relate generally to a semiconductor package and a method of inspecting the semiconductor package, and more particularly relate to a semiconductor package to be received in a test socket for reliability test and a method of inspecting the semiconductor package.

A reliability test (Bias HAST, bias highly accelerated stress test) may be performed on a wafer level semiconductor package (WLP) using a test socket. In the reliability test, moisture may flow into bonding pads (under bump metallurgy) on which conductive bumps are provided. The moisture introduced into a space between the test socket and the semiconductor package may form a water layer (moisture layer), and the water layer may cause corrosive ions of the test socket to come into contact with the bonding pads, resulting in a corrosion phenomenon.

### SUMMARY

Example embodiments provide a semiconductor package having a structure capable of preventing corrosion as a result of being received in a test socket.

Example embodiments provide a method of inspecting the semiconductor package.

According to example embodiments, a semiconductor package includes a semiconductor chip having a first surface and a second surface opposite to the first surface, the semiconductor chip having a plurality of circuit patterns that are provided in the second surface; a redistribution wiring layer provided on the second surface of the semiconductor chip, the redistribution wiring layer having a plurality of redistribution wirings and a plurality of bonding pads, wherein the plurality of redistribution wirings are electrically connected to the plurality of circuit patterns, and the plurality of bonding pads are electrically connected to the plurality of redistribution wirings and exposed from a lower surface of the redistribution wiring layer; a plurality of conductive bumps provided on the plurality of bonding pads, respectively; and a plurality of spacers provided on the lower surface of the redistribution wiring layer, the plurality of spacers configured to accommodate the plurality of conductive bumps in through holes of a test socket and to space the redistribution wiring layer from the test socket.

According to example embodiments, a semiconductor package includes a semiconductor chip having a plurality of circuit patterns formed therein; a redistribution wiring layer provided on the semiconductor chip, the redistribution wiring layer having a plurality of redistribution wirings and a plurality of bonding pads, the plurality of redistribution wirings electrically connected to the plurality of circuit patterns, the plurality of bonding pads electrically connected to the plurality of redistribution wirings and exposed from a lower surface of the redistribution wiring layer; a plurality of conductive bumps provided on the plurality of bonding pads, respectively; and a plurality of spacers respectively provided in corner regions on the lower surface of the redistribution wiring layer. The plurality of spacers are configured to space the lower surface of the redistribution wiring layer from an upper surface of a test socket that has an accommodating space for accommodating the semiconductor chip.

According to example embodiments, in a method of inspecting a semiconductor package, the semiconductor package having a plurality of conductive bumps is provided, the plurality of conductive bumps being provided on a plurality of bonding pads exposed from a lower surface thereof, respectively. A plurality of spacers formed in corner regions on the lower surface of the semiconductor package, respectively, are formed. The semiconductor package is disposed in an accommodating space of a test socket such that the lower surface of the semiconductor package is spaced apart from a bottom surface of the accommodating space by the plurality of spacers. A plurality of interface pins are brought into contact with the plurality of conductive bumps, respectively, to test a reliability of the semiconductor package.

According to example embodiments, a semiconductor package may include a semiconductor chip having a first surface and a second surface opposite to the first surface and having a plurality of circuit patterns provided in the second surface, a redistribution wiring layer provided on the second surface of the semiconductor chip and having a plurality of redistribution wirings and a plurality of bonding pads, the plurality of redistribution wirings being electrically connected to the plurality of circuit patterns, the plurality of bonding pads electrically connected to the plurality of redistribution wirings and exposed from a lower surface, a plurality of conductive bumps provided on the plurality of bonding pads, respectively, and a plurality of spacers provided on the lower surface of the redistribution wiring layer and configured to accommodate the plurality of conductive bumps in through holes of a test socket and to space the redistribution wiring layer from the test socket.

Thus, a reliability test (e.g., Bias HAST, bias highly accelerated stress test) may be performed on the semiconductor package using the test socket. In the reliability test, the plurality of conductive bumps may be accommodated in the through holes of the test socket, respectively. In the process of receiving the plurality of conductive bumps in the through holes respectively, a distance between the redistribution wiring layer of the semiconductor package and the test socket may become closer.

When the distance between the redistribution wiring layer and the test socket becomes closer, the plurality of spacers may space the test socket from the lower surface of the redistribution wiring layer. Since the redistribution wiring layer and the test socket are spaced apart from each other by the plurality of spacers, a water layer may be prevented from being generated between the redistribution wiring layer and the test socket. Since the formation of the water layer is prevented, corrosive ions of the test socket might not contact the bonding pads. A corrosion phenomenon may be prevented from occurring in the bonding pads.

### BRIEF DESCRIPTION OF THE DRAWINGS

Example embodiments will be more clearly understood from the following detailed description taken in conjunction with the accompanying drawings, wherein like reference numerals (when used) indicate corresponding elements throughout the several views. FIGS. 1 to 6 represent non-limiting, example embodiments as described herein.

FIG. 1 is a side view depicting an illustrative semiconductor package in a test socket, in accordance with example embodiments.

FIG. 2 is a cross-sectional view illustrating at least a portion of the semiconductor package shown in FIG. 1.

FIG. 3 is a plan view illustrating a lower surface of the semiconductor package shown in FIG. 2.

FIG. 4 is a side view depicting an illustrative semiconductor package including additional spacers that is in a test socket, in accordance with example embodiments.

FIG. 5 is a plan view illustrating a lower surface of the semiconductor package shown in FIG. 4.

FIG. 6 is a flowchart depicting an illustrative method of inspecting a semiconductor package, in accordance with example embodiments.

### DETAILED DESCRIPTION OF EXAMPLE EMBODIMENTS

Hereinafter, example embodiments will be explained in detail with reference to the accompanying drawings.

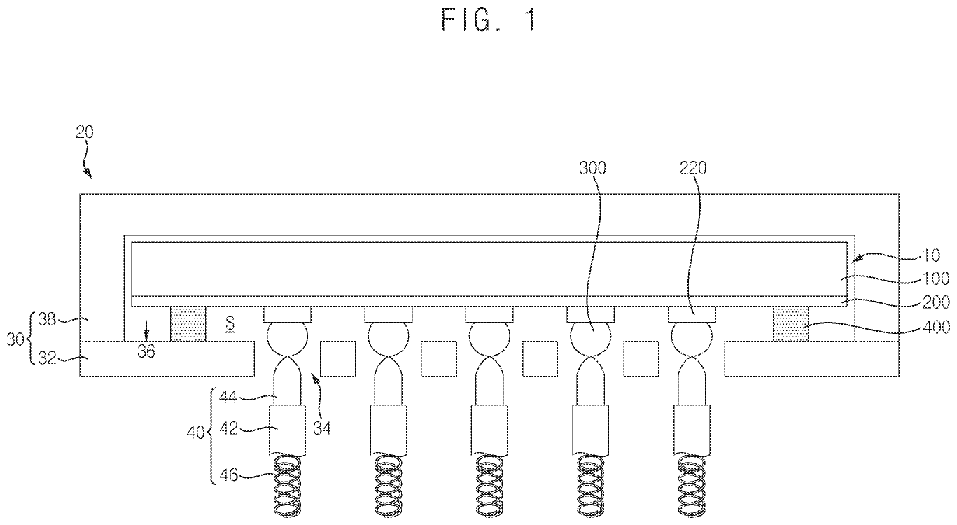

FIG. 1 is a side view illustrating a semiconductor package in a test socket, in accordance with example embodiments.

Referring to FIG. 1, a semiconductor package 10 may be received in an accommodating space S of a test socket 20. The test socket 20 may be electrically connected to the semiconductor package 10 to perform a reliability test (e.g., Bias HAST, bias highly accelerated stress test). The term “connected,” as may be used herein, is broadly intended to include an electrical and/or physical connection, and may include other intervening elements unless stated otherwise. For example, the semiconductor package 10 may include a wafer. The semiconductor package 10 may include a wafer level package (WLP). The reliability test may obtain data relating to temperature, humidity, voltage, and/or current for the semiconductor package 10.

In example embodiments, the test socket 20 may include a body 30 configured to define the accommodating space S for receiving the semiconductor package 10, a test board for testing the semiconductor package 10 that is received in the accommodating space S, and a plurality of interface pins 40 configured to electrically connect the test board and the semiconductor package 10.

The body 30 may include a plate 32 configured to support the semiconductor package 10 and a cover 38 configured to cover the plate 32. The term “cover” (or “covered” or “covering,” or like terms), as may be used herein, is intended to broadly refer to a material, layer or structure being on or over another material, layer or structure, but does not require the material, layer or structure to entirely cover the other material, layer or structure, unless specifically stated otherwise. The accommodating space S of the body 30 may have a bottom surface 36 that is configured to support the semiconductor package 10. The bottom surface 36 of the accommodating space S may be an upper surface of the plate 32. The semiconductor package 10 may be disposed on the upper surface of the plate 32. The plate 32 may have a plurality of through holes 34. The cover 38 may protect the semiconductor package 10 that is received in the accommodating space S from the outside during the reliability test.

The test board may include test circuits configured to perform the reliability test on the semiconductor package 10, and inspection terminals electrically connected to the test circuits. For example, the test board may be connected to an external device to receive power and to exchange data. The test board may be referred to as an electronic board for testing the reliability of the semiconductor package 10.

Each of the interface pins 40 may include a cylindrical pin body 42 having an opened end portion, a contact pin 44 provided in the opened end portion and extending from the pin body 42, and a spring 46 configured to press the opened end portion to the contact pin. The interface pins 40 may electrically connect the semiconductor package 10 and the test board to perform the reliability test on the semiconductor package 10. For example, each of at least a subset of the interface pins 40 may include a pogo pin.

The interface pins 40 may apply driving signals and test signals from the semiconductor package 10 and/or from the test board. The driving signals and the test signals applied to the interface pins 40 may be transmitted to the contact pin 44 through the pin body 42 of each of the interface pins 40, and then, may be transmitted to a corresponding conductive bump 300 of the semiconductor package 10, to perform an electrical test on the semiconductor package 10.

The interface pins 40 may include a conductor, and may electrically connect the test board and the semiconductor package 10. For example, the interface pins 40 may include copper (Cu), aluminum (Al), tungsten (W), nickel (Ni), molybdenum (Mo), gold (Au), silver (Ag), chromium (Cr), Tin (Sn), titanium (Ti), or alloys thereof.

Hereinafter, the semiconductor package 10 will be described in detail.

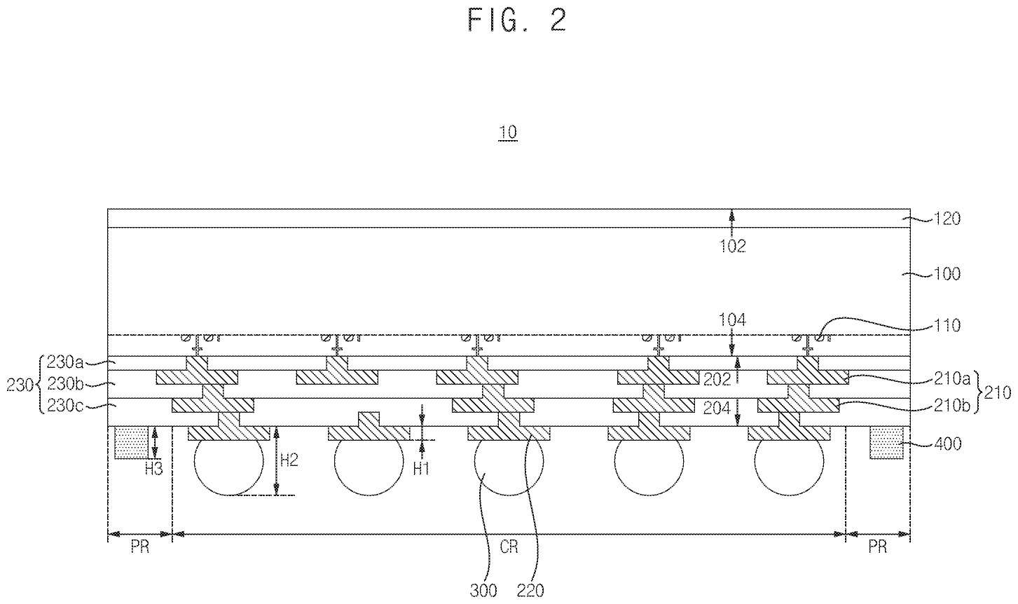

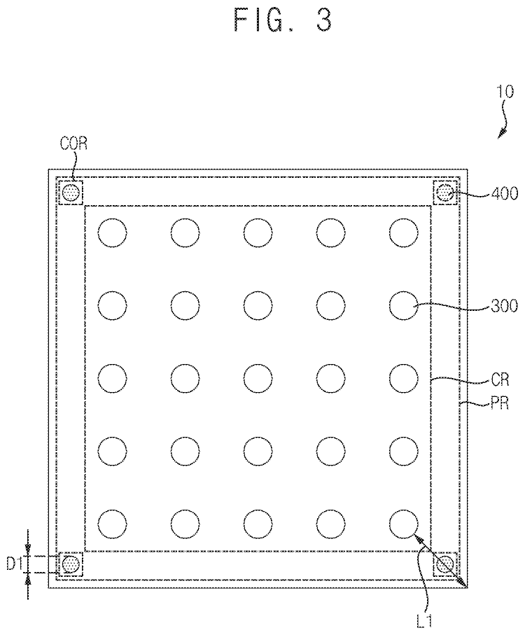

FIG. 2 is a cross-sectional view illustrating the semiconductor package 10 shown in FIG. 1. FIG. 3 is a plan view illustrating a lower surface of the semiconductor package in FIG. 2.

Referring to FIGS. 1 to 3, the semiconductor package 10 may include a semiconductor chip 100 having a first surface 102 and a second surface 104 opposite to the first surface 102, a redistribution wiring layer 200 provided on the second surface 104 of the semiconductor chip 100, a plurality of conductive bumps 300 provided on the redistribution wiring layer 200, and a plurality of spacers 400 provided on the redistribution wiring layer 200. In addition, the semiconductor package 10 may further include a plurality of through electrodes that penetrate (i.e., extend into) a silicon substrate of the semiconductor chip 100, and a protective layer 120 provided on the first surface 102 of the semiconductor chip 100.

In example embodiments, the first surface 102 of the semiconductor chip 100 may be referred to as an inactive surface, and the second surface 104 may be referred to as an active surface. Circuit patterns 110 may be provided in the second surface 104 of the semiconductor chip 100. The second surface 104 may be referred to as a front surface on which the circuit patterns 110 are provided, and the first surface 102 may be referred to as a backside surface.

For example, the silicon substrate of the semiconductor chip 100 may include silicon, germanium, silicon-germanium, or III-V compounds, e.g., gallium phosphide (GaP), gallium arsenide (GaAs), gallium antimonide (GaSb), etc. In some embodiments, the silicon substrate 100 may be a silicon-on-insulator (SOI) substrate, or a germanium-on-insulator (GOI) substrate, although embodiments are not limited thereto.

The circuit patterns 110 may include transistors, diodes, and the like. The circuit patterns 110 may constitute circuit elements. Thus, the semiconductor package 10 may be referred to as a semiconductor device with a plurality of the circuit elements formed therein.

In example embodiments, the redistribution wiring layer 200 may include a plurality of insulating layers 230a, 230b and 230c, collectively 230, and a plurality of redistribution wirings 210a and 210b, collectively 210, provided in the plurality of insulating layers. The redistribution wiring layer 200 may have an upper surface 202 and a lower surface 204 opposite to the upper surface 202. The redistribution wiring layer 200 may include a plurality of bonding pads 220 that are exposed from the lower surface 204 of the redistribution wiring layer 200.

The redistribution wiring layer 200 may include a central region CR and a peripheral region PR surrounding (i.e., extending around) the central region CR. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The redistribution wiring layer 200 may include corner regions COR that are provided in the peripheral region PR. The central region CR of the redistribution wiring layer 200 may be referred to as a region in which the plurality of bonding pads 220 are provided.

The plurality of redistribution wirings 210 may include first and second redistribution wirings 210a and 210b. The plurality of redistribution wirings 210 may be formed by a plating process, an electroless plating process, a vapor deposition process, etc. For example, the plurality of redistribution wirings 210 may include copper (Cu), aluminum (Al), tungsten (W), nickel (Ni), molybdenum (Mo), gold (Au), silver (Ag), chromium (Cr), Tin (Sn), titanium (Ti), or alloys thereof, although embodiments are not limited thereto.

The plurality of insulating layers 230 may include first to third insulating layers 230a, 230b and 230c. The plurality of insulating layers 230 may include a polymer or a dielectric layer, although embodiments are not limited thereto. The plurality of insulating layers 230 may include silicon oxide, carbon doped silicon oxide, silicon carbonitride (SiCN), etc. The plurality of insulating layers 230 may be formed by a vapor deposition process, a spin coating process, etc.

In example embodiments, the plurality of insulating layers 230 may cover the plurality of redistribution wirings 210. The first insulating layer (i.e., an uppermost insulating layer) 230a may be provided on the upper surface 202 of the redistribution wiring layer 200, and the third insulating layer (i.e., a lowermost insulating layer) 230c may be provided on the lower surface 204 of the redistribution wiring layer 200.

In particular, the plurality of bonding pads 220 may be provided on the third insulating layer 230b. The plurality of bonding pads 220 may be provided in the central region CR. Bottom surfaces of the bonding pads 220 may be exposed from the lower surface of the first insulating layer 230a, that is, the lower surface 204 of the redistribution wiring layer 200. For example, each of the bonding pads 220 may have a first height H1 extending from the lower surface 204 of the redistribution wiring layer 200 in a vertical direction perpendicular to the lower surface 204 of the redistribution wiring layer 200.

The first insulating layer 230a may be provided on the second surface 104 of the substrate 100 and may have first openings that expose portions of the circuit pattern 110. The first redistribution wirings 210a may be provided on the first insulating layer 230a, and may be electrically connected to the circuit pattern 110 through the first openings.

The second insulating layer 230b may be provided on the first insulating layer 230a, and may have second openings that expose at least a portion of the first redistribution wirings 210a. The second redistribution wirings 210b may be provided on the second insulating layer 230b, and may be electrically connected to the first redistribution wirings 210a through the second openings.

The third insulating layer 230c may be provided on the second insulating layer 230b, and may have third openings that expose at least a portion of the second redistribution wirings 210b. The bonding pads 220 may be provided on the third insulating layer 230c, and may be electrically connected to the second redistribution wirings 210b through the third openings. For example, the bonding pads 220 may include copper (Cu), aluminum (Al), tungsten (W), nickel (Ni), molybdenum (Mo), gold (Au), silver (Ag), chromium (Cr), tin (Sn), titanium (Ti) or alloys thereof, although embodiments are not limited thereto.

In example embodiments, the plurality of conductive bumps 300 may be provided on the lower surface 204 of the redistribution wiring layer 200. The plurality of conductive bumps 300 may be provided on the plurality of bonding pads 220, respectively. The plurality of conductive bumps 300 may be provided in the central region CR. For example, each of the plurality of conductive bumps 300 may have a second height H2 extending from the lower surface 204 of the redistribution wiring layer 200 in the vertical direction.

In a process of the reliability test, at least portions of the conductive bumps 300 may be disposed in the plurality of through holes 34 of the plate 32, respectively. The through holes 34 of the plate 32 may be aligned with (in the vertical direction) and adapted to receive at least portions of the conductive bumps 300 such that the conductive bumps 300 may stably make contact with the interface pins 40.

The conductive bumps 300 respectively in the plurality of through holes 34 may make contact with the interface pins 40, respectively. The conductive bumps 300 in the plurality of through holes 34 may be electrically connected to the test board through the interface pins 40. The conductive bumps 300 may be brought into contact with the interface pins 40 to perform the reliability test.

The conductive bumps 300 may provide electrical paths for electrically connecting the semiconductor package 10 to other semiconductor devices. The semiconductor package 10 may be mounted to the other semiconductor device via the conductive bumps 300. For example, the conductive bumps 300 may include micro bumps (μBumps). The conductive bumps 300 may include controlled collapse chip connection (C4) bumps.

In example embodiments, the protective layer 120 may be provided on the first surface 102 of the semiconductor chip 100. The protective layer 120 may include an insulating material to protect the semiconductor chip 100 from the outside. The protective layer 120 may include, for example, an oxide layer or a nitride layer, or may include a double layer of an oxide layer and a nitride layer, although embodiments are not limited thereto. The protective layer 120 may include an oxide layer, for example, a silicon oxide layer (SiO₂) formed by a high-density plasma chemical vapor deposition (HDP-CVD) process, although embodiments are not limited thereto.

In example embodiments, the plurality of spacers 400 may be provided on the lower surface 204 of the redistribution wiring layer 200. The plurality of spacers 400 may be provided on the third insulating layer 230c. When the semiconductor package 10 is disposed in the accommodating space S of the test socket 20, the plurality of spacers 400 may be interposed between the lower surface 204 of the redistribution wiring layer 200 and the bottom surface 36 of the test socket 20, so that the lower surface 204 of the redistribution wiring layer 200 is spaced apart in the vertical direction from the bottom surface 36 of the test socket 20.

The plurality of spacers 400 may be provided in the peripheral region PR on the lower surface 204 of the redistribution wiring layer 200. The plurality of spacers 400 may be provided in the peripheral region PR to support the semiconductor package 10. Since the plurality of spacers 400 are provided in the peripheral region PR, the plurality of spacers 400 may stably support the semiconductor package 10. The plurality of spacers 400 may be provided in the corner regions COR in the peripheral region PR, respectively. The plurality of spacers 400 may stably support the semiconductor package 10 on the corner regions COR.

Each of the spacers 400 may have a third height H3 extending from the lower surface 204 of the redistribution wiring layer 200 in the vertical direction. The third height H3 of each of the spacers 400 may be greater than the first height H1 of each of the bonding pads 220. The third height H3 of each of the spacers 400 may be smaller than the second height H2 of each of the conductive bumps 300. For example, the third height H3 may be within a range of about 10 μm to 200 μm.

Since the spacers 400 have the third height H3, the reliability test may be performed more stably on the semiconductor package 10. In particular, when the semiconductor package 10 is disposed in the accommodating space S of the test socket 20, the spacers 400 may support the semiconductor package 10 from the bottom surface 36 of the accommodating space S. Since the third height H3 of each of the spacers 400 is greater than the first height H1 of each of the bonding pads 220, the bonding pads 220 may be spaced apart from the bottom surface 36 of the accommodating space S. Since the bonding pads 220 are spaced apart from the bottom surface 36 of the accommodating space S, a water layer may be prevented from being generated between the bonding pads 220 and the bottom surface 36 of the accommodating space S.

Since the third height H3 of each of the spacers 400 is smaller than the second height H2 of each of the conductive bumps 300, in the process of the reliability test, the conductive bumps 300 may be configured to be received in the through holes 34 of the plate 32 respectively. Since the third height H3 of each of the spacers 400 is smaller than the second height H2 of each of the conductive bumps 300, in the process of the reliability test, the conductive bumps 300 may stably make contact with the interface pins 40.

Each of the plurality of spacers 400 may have a first diameter DI in a horizontal direction parallel to the lower surface 204 of the redistribution wiring layer 200. Each of the plurality of spacers 400 having the first diameter DI may stably support the semiconductor package 10. For example, the conductive bumps 300 provided adjacent to the corner regions COR may be spaced apart in the horizontal direction from outer end portions of the corner regions COR by a first distance L1. A difference between the first diameter DI and the first distance L1 may be within a range of about 10 μm to 100 μm.

The plurality of spacers 400 may include structures for stably supporting the semiconductor package 10. For example, the spacers 400 may include a cylinder shape, a square pillar shape, a circular cone shape, a quadrangular pyramid shape, a hemisphere shape, a circular truncated cone shape, a frustum of quadrangular pyramid, etc., although embodiments are not limited thereto.

The plurality of spacers 400 may include an elastic material to stably support the semiconductor package 10 and to absorb an impact applied to the semiconductor package 10. For example, the elastic material may include rubber. Alternatively, the plurality of spacers 400 may include a metal material or a plastic material to strongly support the semiconductor package 10. For example, the metal material may include copper (Cu), aluminum (Al), tungsten (W), nickel (Ni), molybdenum (Mo), gold (Au), silver (Ag), chromium (Cr), tin (Sn), titanium (Ti) or alloys thereof. For example, the plastic material may include polyethylene (PE), polypropylene (PP), polystyrene (PS), polyethylene terephthalate (PET), polyamides (PA), polyester (PES), polyvinyl chloride (PVC), polyurethanes (PU), polycarbonate (PC), polyvinylidene chloride (PVDC), etc.

As mentioned above, the reliability test may be performed on the semiconductor package 10 through the test socket 20. In the reliability test, the plurality of conductive bumps 300 may be accommodated (i.e., oriented or aligned) in the through holes 34 of the test socket 20, respectively. In the process of receiving the plurality of conductive bumps 300 in the through holes 34 respectively, the distance between the redistribution wiring layer 200 of the semiconductor package 10 and the test socket 20 may become closer.

When the distance between the redistribution wiring layer 200 and the test socket 20 becomes closer, the plurality of spacers 400 may space the test socket 20 from the lower surface 204 of the redistribution wiring layer 200. Since the redistribution wiring layer 200 and the test socket 20 are spaced apart from each other by the plurality of spacers 400, the water layer may be prevented from being generated between the redistribution wiring layer 200 and the test socket 20. Since the formation of the water layer is prevented, corrosive ions of the test socket 20 might not contact the bonding pads 220. A corrosion phenomenon may be prevented from occurring in the bonding pads 220.

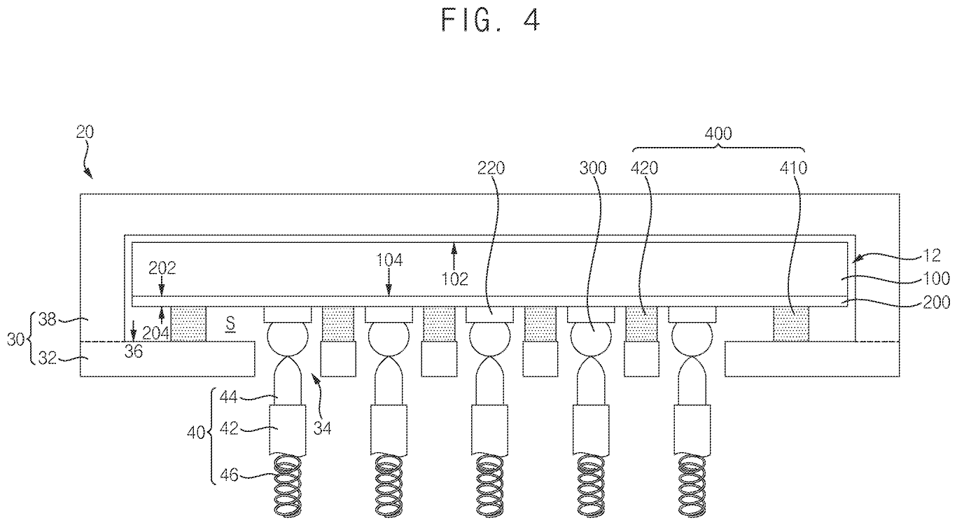

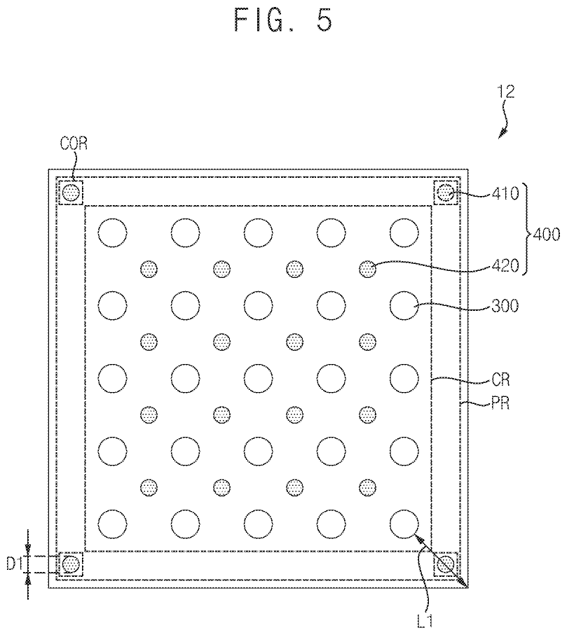

FIG. 4 is a side view illustrating a semiconductor package 12 including additional spacers that are accommodated (i.e., oriented or aligned) in a test socket, in accordance with example embodiments. FIG. 5 is a plan view illustrating a lower surface of the semiconductor package 12 shown in FIG. 4. The semiconductor package 12 may be substantially the same as or similar to the semiconductor package 10 described with reference to FIGS. 1 to 3 except for the inclusion of additional spacers. Thus, the same or similar components are denoted by the same or similar reference numerals, and repeated descriptions of the same components will be omitted.

Referring to FIGS. 4 and 5, the semiconductor package 12 may be configured to be received in an accommodating space S of a test socket 20. The semiconductor package 12 may include a semiconductor chip 100 having a first surface 102 and a second surface 104 opposite to the first surface 102, a redistribution wiring layer 200 provided on the second surface 104 of the semiconductor chip 100, a plurality of conductive bumps 300 provided on the redistribution wiring layer 200, and a plurality of spacers 400 provided on the redistribution wiring layer 200.

In example embodiments, the plurality of spacers 400 may be provided on a lower surface 204 of the redistribution wiring layer 200. When the semiconductor package 12 is oriented in the accommodating space S of the test socket 20, the spacers 400 may space the lower surface 204 of the redistribution wiring layer 200 from a bottom surface 36 of the test socket 20.

The spacers 400 may include a plurality of first posts 410 respectively provided in the peripheral region PR, and more particularly in the corner regions COR, on the lower surface 204 of the redistribution wiring layer 200, and a plurality of second posts 420 provided in a central region CR on the lower surface 204 of the redistribution wiring layer 200.

The plurality of first posts 410 may be provided in the peripheral region PR to support the semiconductor package 12. Since the plurality of first posts 410 are provided in the peripheral region PR, the semiconductor package 12 may be stably supported in the accommodating space S.

The plurality of second posts 420 may be provided in the central region CR. The plurality of second posts 420 may be provided, for example, between bonding pads 220 that are exposed from the lower surface 204 of the redistribution wiring layer 200. The plurality of second posts 420 may be provided between the conductive bumps 300 that are provided on the bonding pads 220.

The plurality of second posts 420 may be provided in an area of the central region CR that does not interfere with the performance of the semiconductor package 12. For example, when the semiconductor package 12 is mounted on another semiconductor device, the second posts 420 might not interfere with electrical connection between the semiconductor package 12 and the other semiconductor device.

In the reliability test, the second posts 420 may contact the bottom surface 36 of the test socket 20. The second posts 420 may be provided between the through holes 34 to support the semiconductor package 12. Since the second posts 420 support the semiconductor package 12 between the through holes 34, a warpage of the semiconductor package 12 may be prevented or reduced. Even for a semiconductor package 12 that may exhibit some warpage, the second posts 420 may stably support the semiconductor package 12.

Hereinafter, a method of inspecting the semiconductor package 10 using the test socket 20 in FIG. 1 will be described.

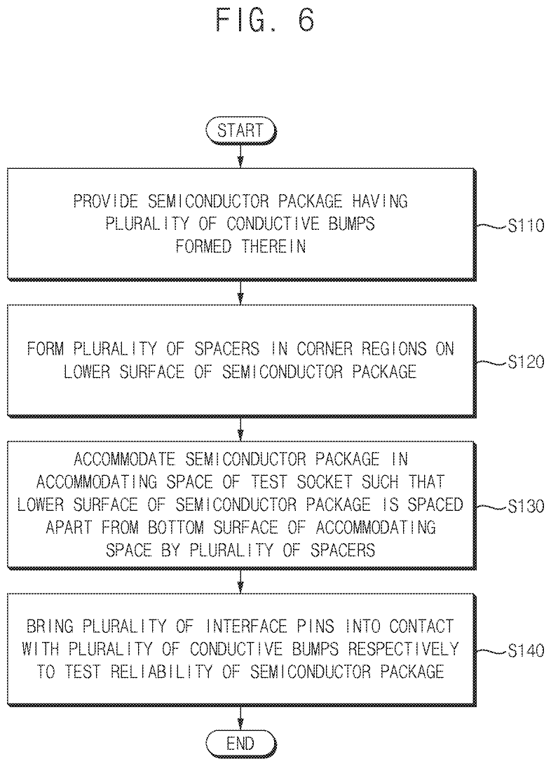

FIG. 6 is a flowchart illustrating an example method of inspecting a semiconductor package, in accordance with example embodiments.

Referring to FIGS. 1 to 3 and 6, first, a semiconductor package 10 having a plurality of conductive bumps 300 may be provided (S110). The plurality of conductive bumps 300 may be provided on a plurality of bonding pads 220, respectively. The plurality of bonding pads 220 may be exposed from a lower surface 204 of the semiconductor package 10.

In example embodiments, a semiconductor chip 100 having a first surface 102 and a second surface 104 opposite to the first surface 102 may be provided, and a redistribution wiring layer 200 may be formed on the second surface 104 of the semiconductor chip 100.

The redistribution wiring layer 200 may have a central region CR and a peripheral region PR surrounding (i.e., extending around) the central region CR. The plurality of bonding pads 220 may be formed to be exposed from the lower surface 204 of the redistribution wiring layer 200 in the central region CR.

The plurality of conductive bumps 300 may be respectively formed on the plurality of bonding pads 220 that are exposed to the lower surface 204 of the redistribution wiring layer 200. The plurality of conductive bumps 300 may be formed in the central region CR. The conductive bumps 300 may provide electrical paths for electrically connecting the semiconductor package 10 to other semiconductor devices. For example, the conductive bumps 300 may include micro bumps (μBumps). The conductive bumps 300 may include C4 bumps.

In particular, a plurality of spacers 400 may be respectively formed in corner regions COR on the lower surface 204 of the semiconductor package 10 (S120).

In example embodiments, the plurality of spacers 400 may be formed in the peripheral region PR on the lower surface 204 of the redistribution wiring layer 200. The plurality of spacers 400 may be provided in the corner regions COR in the peripheral region PR, respectively.

Each of the spacers 400 may be formed to have a third height H3 extending from the lower surface 204 of the redistribution wiring layer 200 in the vertical direction. The third height H3 of each of the spacers 400 may be greater than a first height H1 of each of the bonding pads 220 extending from the lower surface 204 of the redistribution wiring layer 200 in the vertical direction. The third height H3 of each of the spacers 400 may be smaller than a second height H2 of each of the conductive bumps 300 extending from the lower surface 204 of the redistribution wiring layer 200 in the vertical direction. For example, the third height H3 may be within a range of about 10 μm to 200 μm.

Alternatively, before the plurality of conductive bumps 300 are formed, the plurality of spacers 400 may be formed on the lower surface 204 of the redistribution wiring layer 200. First, the plurality of spacers 400 may be formed in the peripheral region PR on the lower surface 204 of the redistribution wiring layer 200, and then, the plurality of conductive bumps 300 may be formed on the plurality of bonding pads 220, respectively.

Then, the semiconductor package 10 may be accommodated (i.e., oriented or aligned) in an accommodating space S such that the lower surface 204 of the semiconductor package 10 is spaced apart from a bottom surface 36 of the accommodating space S of a test socket 20 by the plurality of spacers 400 (S130).

In example embodiments, the semiconductor package 10 may be supported from the bottom surface 36 of the test socket 20 by the plurality of spacers 400. Since the plurality of spacers 400 are provided in the peripheral region PR, the semiconductor package 10 may be stably supported.

When the semiconductor package 10 is accommodated in the accommodating space S of the test socket 20, the semiconductor package 10 may be supported from the bottom surface 36 of the accommodating space S by the plurality of spacers 400. Since the third height H3 of each of the spacers 400 is greater than the first height H1 of each of the bonding pads 220, the bonding pads 220 may be spaced apart from the bottom surface 36 of the accommodating space S. Since the third height H3 of each of the spacers 400 is smaller than the second height H2 of each of the conductive bumps 300, the conductive bumps 300 may be aligned within through holes 34 of the test socket 20.

Then, a plurality of interface pins 40 may be respectively brought into contact with the plurality of conductive bumps 300 to test a reliability of the semiconductor package 10 (S140).

In example embodiments, the test socket 20 may be electrically connected to the semiconductor package 10 through the interface pins 40 to perform a reliability test (e.g., Bias HAST, bias highly accelerated stress test). The reliability test may obtain data relating to temperature, humidity, voltage, and/or current for the semiconductor package 10.

The test socket 20 may apply a driving signal and a test signal to the semiconductor package 10 through the plurality of interface pins 40. The driving signal and the test signal may be transmitted to the conductive bumps 300 of the semiconductor package 10 to perform an electrical test on the semiconductor package 10.

Since the bonding pads 220 are spaced apart from the bottom surface 36 of the accommodating space S, a water layer may be prevented from being generated between the bonding pads 220 and the bottom surface 36 of the accommodating space S.

Since the third height H3 of each of the spacers 400 is smaller than the second height H2 of each of the conductive bumps 300, in a process of the reliability test, the conductive bumps 300 may stably make contact with the interface pins 40.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A semiconductor package, comprising:
a semiconductor chip having a first surface and a second surface opposite to the first surface, the semiconductor chip having a plurality of circuit patterns in the second surface;
a redistribution wiring layer on the second surface of the semiconductor chip, the redistribution wiring layer having a plurality of redistribution wirings and a plurality of bonding pads, wherein the plurality of redistribution wirings are electrically connected to the plurality of circuit patterns, and the plurality of bonding pads are electrically connected to the plurality of redistribution wirings and exposed from a lower surface of the redistribution wiring layer;
a plurality of conductive bumps on the plurality of bonding pads, respectively; and
a plurality of spacers on the lower surface of the redistribution wiring layer, the plurality of spacers configured to align the plurality of conductive bumps with respective through holes of a test socket and to space the redistribution wiring layer from the test socket in a first direction perpendicular to the lower surface of the redistribution wiring layer.

2. The semiconductor package of claim 1, wherein the plurality of spacers includes first posts respectively in corner regions on the lower surface of the redistribution wiring layer.

3. The semiconductor package of claim 2, wherein the plurality of spacers further includes second posts on the lower surface of the redistribution wiring layer and respectively between the plurality of conductive bumps.

4. The semiconductor package of claim 1, wherein each of the plurality of spacers has a third height extending from the lower surface of the redistribution wiring layer in the first direction, and
each of the plurality of conductive bumps has a second height extending from the lower surface of the redistribution wiring layer in the first direction, the second height being greater than the third height.

5. The semiconductor package of claim 4, wherein the third height is within a range of about 10 μm to 200 μm.

6. The semiconductor package of claim 4, wherein each of the plurality of bonding pads has a first height extending from the lower surface of the redistribution wiring layer in the first direction, the first height being less than the third height.

7. The semiconductor package of claim 1, wherein each of the plurality of spacers has one of a cylinder shape, a square pillar shape, a circular cone shape, a quadrangular pyramid shape, a hemisphere shape, a circular truncated cone shape, and a frustum of a quadrangular pyramid shape.

8. The semiconductor package of claim 1, wherein each of the plurality of spacers includes at least one of rubber, copper (Cu), aluminum (Al), tungsten (W), nickel (Ni), molybdenum (Mo), gold (Au), silver (Ag), chromium (Cr), tin (Sn), titanium (Ti), polyethylene (PE), polypropylene (PP), polystyrene (PS), polyethylene terephthalate (PET), polyamides (PA), polyester (PES), polyvinyl chloride (PVC), polyurethanes (PU), polycarbonate (PC) and polyvinylidene chloride (PVDC).

9. The semiconductor package of claim 1, wherein each of the plurality of bonding pads includes at least one of copper (Cu), aluminum (Al), tungsten (W), nickel (Ni), molybdenum (Mo), gold (Au), silver (Ag), chromium (Cr), tin (Sn) and titanium (Ti).

10. The semiconductor package of claim 1, wherein a plurality of interface pins is configured to contact the plurality of conductive bumps through the respective through holes of the test socket to perform a reliability test of the plurality of circuit patterns and the plurality of redistribution wirings.

11. A semiconductor package, comprising:
a semiconductor chip having a plurality of circuit patterns formed therein;
a redistribution wiring layer provided on the semiconductor chip, the redistribution wiring layer having a plurality of redistribution wirings and a plurality of bonding pads, the plurality of redistribution wirings electrically connected to the plurality of circuit patterns, the plurality of bonding pads electrically connected to the plurality of redistribution wirings and exposed from a lower surface of the redistribution wiring layer;
a plurality of conductive bumps on the plurality of bonding pads, respectively; and
a plurality of spacers, at least a subset of the plurality of spacers respectively in corner regions on the lower surface of the redistribution wiring layer, the plurality of spacers configured to space the lower surface of the redistribution wiring layer from an upper surface of a test socket that includes a space therein configured to receive the semiconductor chip.

12. The semiconductor package of claim 11, wherein at least one of the plurality of spacers is provided in a central region on the lower surface of the redistribution wiring layer.

13. The semiconductor package of claim 11, wherein each of the plurality of spacers has a third height extending from the lower surface of the redistribution wiring layer in a first direction perpendicular to the lower surface of the redistribution wiring layer, and
each of the plurality of conductive bumps has a second height extending from the lower surface of the redistribution wiring layer in the first direction, the second height being greater than the third height.

14. The semiconductor package of claim 13, wherein the third height is within a range of about 10 μm to 200 μm.

15. The semiconductor package of claim 13, wherein each of the plurality of bonding pads has a first height extending from the lower surface of the redistribution wiring layer in the first direction, the first height being less than the third height.

16. The semiconductor package of claim 11, wherein each of the plurality of spacers has one of a cylinder shape, a square pillar shape, a circular cone shape, a quadrangular pyramid shape, a hemisphere shape, a circular truncated cone shape, and a frustum of a quadrangular pyramid shape.

17. The semiconductor package of claim 11, wherein each of the plurality of spacers includes at least one of rubber, copper (Cu), aluminum (Al), tungsten (W), nickel (Ni), molybdenum (Mo), gold (Au), silver (Ag), chromium (Cr), tin (Sn), titanium (Ti), polyethylene (PE), polypropylene (PP), polystyrene (PS), polyethylene terephthalate (PET), polyamides (PA), polyester (PES), polyvinyl chloride (PVC), polyurethanes (PU), polycarbonate (PC) and polyvinylidene chloride (PVDC).

18. The semiconductor package of claim 11, wherein each of the plurality of bonding pads includes at least one of copper (Cu), aluminum (Al), tungsten (W), nickel (Ni), molybdenum (Mo), gold (Au), silver (Ag), chromium (Cr), tin (Sn) and titanium (Ti).

19. The semiconductor package of claim 11, wherein a plurality of interface pins is configured to contact the plurality of conductive bumps through the respective through holes of the test socket to perform a reliability test of the plurality of circuit patterns and the plurality of redistribution wirings.

20. A semiconductor package, comprising:
a semiconductor chip having a first surface and a second surface opposite to the first surface, the semiconductor chip having a plurality of circuit patterns in the second surface;
a redistribution wiring layer on the second surface of the semiconductor chip, the redistribution wiring layer having a plurality of redistribution wirings and a plurality of bonding pads, wherein the plurality of redistribution wirings are electrically connected to the plurality of circuit patterns, and the plurality of bonding pads are electrically connected to the plurality of redistribution wirings and exposed from a lower surface of the redistribution wiring layer;
a plurality of conductive bumps on the plurality of bonding pads, respectively; and
a plurality of spacers on the lower surface of the redistribution wiring layer, the plurality of spacers configured to space the redistribution wiring layer from a test socket that includes a space therein configured to receive the semiconductor chip, in a first direction perpendicular to the lower surface of the redistribution wiring layer,
wherein the plurality of spacers includes first posts respectively provided in corner regions on the lower surface of the redistribution wiring layer.

21. (canceled)
